(19) United States
(12) Patent Application Publication
(10) Pub. No.: US 2026/0297800 A1
(43) Pub. Date: Oct. 1, 2026

(54) Systems and Methods for Modifying Crystal Growth Processes Based on Sensor Data

(71) Applicant: Wolfspeed, Inc., Durham, NC (US)

(72) Inventors: Steven Herbert Griffiths, Morrisville, NC (US); Benjamin Lefler Layne, Durham, NC (US); Caleb Andrew Kent, Durham, NC (US)

(21) Appl. No.: 19/213,589

(22) Filed: May 20, 2025

Related U.S. Application Data
(60) Provisional application No. 63/779,885, filed on Mar. 28, 2025.

(51) Int. Cl. C30B 23/00; C23C 14/06; C23C 14/24; C23C 14/54; C30B 23/06; C30B 29/36

(52) U.S. Cl. CPC C30B 23/002; C23C 14/0635; C23C 14/243; C23C 14/54; C30B 23/06; C30B 29/36

(57) ABSTRACT

An example method includes obtaining, during a crystal growth process, measured data of a physical property of a crystalline material (e.g., silicon carbide crystalline material) in a crystal growth assembly. The example method includes determining, based on the measured data, a crystal parameter associated with the crystalline material. The example method includes adjusting, based on the crystal parameter, one or more process parameters of the crystal growth process during the crystal growth process.

### PRIORITY CLAIM

The present application claims the benefit of priority of U.S. Provisional Application Ser. No. 63/779,885, filed on Mar. 28, 2025, which is incorporated herein by reference.

### FIELD

The present disclosure relates generally to crystal growth systems, such as silicon carbide crystal growth systems for growing crystalline silicon carbide semiconductor workpieces for fabrication of semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

### SUMMARY

Aspects and advantages of embodiments of the present disclosure will be set forth in part in the following description, or can be learned from the description, or can be learned through practice of the embodiments.

In an aspect, the present disclosure provides an example method. In some implementations, the example method includes obtaining, during a crystal growth process, measured data of a physical property of a crystalline material in a crystal growth system. In some implementations, the example method includes determining, based on the measured data, a crystal parameter associated with the crystalline material. In some implementations, the example method includes adjusting, based on the crystal parameter, one or more process parameters of the crystal growth process during the crystal growth process.

In an aspect, the present disclosure provides an example crystal growth system. In some implementations, the example crystal growth system includes a seed holder configured to hold a seed crystal for growth of the silicon carbide crystalline material. In some implementations, the example crystal growth system includes a crucible at least partially defining a crystal growth chamber. In some implementations, the example crystal growth system includes a source material. In some implementations, the example crystal growth system includes one or more heating elements. In some implementations, the example crystal growth system includes a sensor for measuring a physical property of the crystalline material. In some implementations, the example crystal growth system includes a control system configured to adjust one or more process parameters during a crystal growth process based at least in part on the physical property of the crystalline material.

In an aspect, examples of the present disclosure are directed to a system for monitoring growth of a crystalline material. The system includes one or more sensors. The system includes processing circuitry configured to perform operations. The operations include: obtaining, during a crystal growth process, measured data indicative of a physical property of a crystalline material in a crystal growth system; determining, based on the measured data, a crystal parameter associated with the crystalline material; and adjusting, based on the crystal parameter, one or more process parameters of the crystal growth process.

In an aspect, the present disclosure provides an example method. In some implementations, the example method includes obtaining, during a crystal growth process, one or more x-ray images indicative of a physical property of a crystalline material in a crystal growth system. In some implementations, the example method includes determining, based on the one or more x-ray images, a crystal parameter associated with the crystalline material. In some implementations, the example method includes adjusting, based on the crystal parameter, one or more process parameters of the crystal growth process.

In an aspect, the present disclosure provides an example method. In some implementations, the example method includes obtaining, during a crystal growth process, inductive current data indicative of a physical property of a crystalline material in a crystal growth system. In some implementations, the example method includes determining, based on the inductive current data, a crystal parameter associated with the crystalline material. In some implementations, the example method includes adjusting, based on the crystal parameter, one or more process parameters of the crystal growth process.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a system for real-time monitoring of crystal growth processes according to example aspects of the present disclosure.

FIG. 2 depicts a cross-sectional schematic diagram of an example crystal growth system for use in a crystal growth process according to example aspects of the present disclosure.

FIG. 3 depicts a top-down view of a crystal growth system according to example aspects of the present disclosure.

FIG. 4 depicts a cross-sectional diagram of an example crystal growth system according to example aspects of the present disclosure.

FIG. 5 depicts a cross-sectional diagram of an example crystal growth system according to example aspects of the present disclosure.

FIG. 6 depicts a cross-sectional diagram of an example crystal growth system according to example aspects of the present disclosure.

FIG. 7 depicts an example embodiment of the crystal growth system as a continuous feed PVT system according to example aspects of the present disclosure.

FIG. 8 depicts a block diagram of an example method according to example aspects of the present disclosure.

FIG. 9 depicts a block diagram of an example method according to example aspects of the present disclosure.

FIG. 10 depicts a block diagram of an example method according to example aspects of the present disclosure.

FIG. 11 depicts a block diagram of an example computing system according to example aspects of the present disclosure.

FIG. 12 depicts a cross-sectional diagram of an example crystal growth system according to example aspects of the present disclosure.

FIG. 13 depicts a cross-sectional diagram of an example crystal growth system according to example aspects of the present disclosure.

FIG. 14 depicts a cross-sectional diagram of an example crystal growth system according to example aspects of the present disclosure.

FIG. 15 depicts a cross-sectional diagram of an example crystal growth system according to example aspects of the present disclosure.

FIG. 16 depicts a cross-sectional diagram of an example crystal growth system according to example aspects of the present disclosure.

FIG. 17 depicts a cross-sectional diagram of an example crystal growth system according to example aspects of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems and methods for growing semiconductor crystals, such as crystalline silicon carbide (SiC) (e.g., single crystal SiC) or other crystalline material. Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Aspects of the present disclosure are discussed with reference to growing silicon carbide (SiC) crystalline material. Those of ordinary skill in the art, using the disclosures provided herein, will understand that aspects of the present disclosure may be used with crystal growth systems for growing other types of crystalline material, such as aluminum nitride (AlN) or other materials.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

Variations in crystal parameters (e.g., height, mass, growth rate, shape, crystal stress, doping density, etc.) may lead to variations in yield in crystal growth processes. The quality of the SiC crystal can vary along the height of the boule. As used herein, “quality” of the SiC crystal may refer to various aspects of a crystal that impact yield of the crystal and may refer, for example, to dislocation density, micropipe distribution, and other measurable descriptors associated with the crystal. Discrepancies in crystal quality may be due to changes or variations in growth conditions as the process progresses.

For example, temperature gradients may shift slightly or impurities may accumulate, leading to defects in certain regions of the boule. The lower and upper parts of the boule might exhibit more defects than a middle section. This can be because as the height of the boule increases, thermal stress can build up due to temperature differentials within the crystal. This can lead to cracking or other structural issues, particularly near the top of the boule. Accordingly, taller boules may also experience significant variations in temperature and gas flow dynamics, leading to non-uniform growth rates and increased defect density in certain areas. Additionally, variations in yield, including variations in quality, may occur between growth cycles and across various crystal growth systems. Crystal yield consistency may be improved by selecting appropriate growth methods (e.g., process recipes) based on the crystal growth cycle and assembly, however not all inconsistencies may be eliminated.

Therefore, in-situ monitoring of crystal growth processes may provide for improved crystal yield consistency by monitoring a crystal growth chamber as the crystal grows and making adjustments to the crystal growth process as deemed necessary. Although, the extreme conditions necessary to grow SiC crystals provide unique challenges and limitations. For instance, the high temperatures (e.g., excess of 1800° C., such as excess of 2000 degrees ° C.) and low pressure (e.g., sub 10 torr) requirements of growth processes, such as PVT processes, pose challenges for most candidate sensing devices for monitoring and measuring crystal growth.

Accordingly, example aspects of the present disclosure are directed to systems and methods for in-situ monitoring and modification of crystal growth processes. More particularly, example aspects of the present disclosure are directed to obtaining various in-situ measurements of the physical properties of a crystalline material during a crystal growth process; determining, based on the measurements, a crystal parameter of the crystalline material; and adjusting one or more process parameters of the crystal growth process based on the parameter in real time during the crystal growth process.

For instance, as an example, one or more x-ray topography images may be taken of the crystalline material within a crystal growth chamber during a crystal growth process. Subsequently, a crystal parameter (e.g., height, mass, shape, growth rate, doping level, crystal stress, one or more optical properties, uniformity, etc.) may be determined from the one or more x-ray topography images. Then, based on the crystal parameter (e.g., height, mass, shape, growth rate, doping level, crystal stress, one or more optical properties, uniformity, etc.), one or more process parameters of the crystal growth process may be adjusted.

As used herein, a physical property of a crystalline material grown during a crystal growth process may refer to, for instance, a current physical dimension such as height or diameter, a current mass, a thermal conductivity, a crystallographic structure, growth face morphology, purity or incorporation of impurities, a defect density, doping level, or other physical property. In some examples, a physical property may refer to a measurement indicative of mechanical behavior, such as elastic and plastic properties that determine strain or stress states in a crystal.

As used herein, crystal parameters are parameters associated with the crystalline material grown during the crystal growth process. Example crystal parameters include height, mass, shape, growth rate, doping, crystal stress, one or more optical properties, uniformity, etc., of the crystalline material during a crystal growth process.

According to examples of the present disclosure, one or more process parameters of a crystal growth process may be adjusted based on the crystal parameter(s). Process parameters are any parameters that may be controlled during a crystal growth process to affect crystal growth. Example process parameters include temperature, pressure, coolant flow rate, flux, growth segment time duration, heating element position, crucible position, crucible position relative to heating element position, crystal position, source position, rotation of the crystal, and/or any of the controllable operation parameters of the crystal growth system (e.g., heating element temperature, heating element power consumption, mass flow rate of species into the chamber, etc.). The process parameter can be any controllable process variable or combination of process variables used to affect a crystal growth process.

In some embodiments, a crystal growth process may include a plurality of growth segments, each with unique process parameters. In some instances, data associated with the crystalline material may be obtained during each of the plurality of growth segments. Each crystal growth segment may be a period of time during which data associated with a physical property of the crystalline material is obtained, a crystal parameter (e.g., height, mass, shape, growth rate, doping level, crystal stress, one or more optical properties, uniformity, etc.) is determined, and a process parameter (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) is adjusted, according to examples of the present disclosure. A crystal growth process may have any number of crystal growth segments at any level of resolution. Individual crystal growth segments may have the same duration or different durations.

Various data indicative of a physical property of a crystalline material may be obtained during a crystal growth process to determine crystal parameters of the crystalline material. For instance, the measured data may be image data (e.g., x-ray topography image date), such as one or more images of a growth surface of the crystalline material, or a two-dimensional representation of three-dimensional data associated with the crystalline material (e.g., a 3-D model of the crystalline material). Alternatively, in some embodiments, the data may comprise ultrasound data, acoustic data, laser data, optical data, inductive current data, or other measured data.

In some embodiments, the measured data may be obtained via an imaging device. In some embodiments, the imaging device may be actuatable between multiple imaging detectors allowing for measured data to be obtained from multiple planes. Each imaging detector may include an imaging surface proximate to the outer surface of the crystal growth chamber. The imaging detectors, in combination with the imaging device, may obtain the measured data associated with the crystalline material within the crystal growth chamber. Alternatively, or in addition, the measured data may be obtained from a sensing coil positioned around the outer surface of the crystal growth chamber. In these embodiments, the crystalline material may be positioned within the sensing coil and the sensing coil may generate inductive current data.

In some embodiments, the measured data associated with the crystalline material may be x-ray data. For instance, the measured data of the crystalline material may be x-ray image data, such as one or more x-ray images, or x-ray tomography data. In embodiments including x-ray image data, said x-ray data may be obtained using an imaging device proximate to an outer surface of the crystal growth chamber. The imaging device may be actuatable between multiple imaging detectors allowing for x-ray images of the crystalline material from multiple planes. Each imaging detector may include an imaging surface proximate to the outer surface of the crystal growth chamber. The imaging detectors, in combination with the imaging device, may develop x-ray images of the crystalline material within the crystal growth chamber.

Similarly, various process parameters of the crystal growth process may be adjusted based on the measured data from the crystalline material and the determined crystal parameters. For instance, the various process parameters may include one or more of temperature (e.g., the temperature of the heating elements during a given growth segment of a crystal growth process), pressure, vapor pressure, coolant flow rate, vapor flux, growth segment duration, heating element position, crucible position, crucible position relative to heating element position, crystal position, source position, rotation of the crystal, and/or any of the controllable operation parameters. It should be appreciated that more than one process parameter may be adjusted based on the determined crystal parameter. Any combination or variation of process parameters (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) may be adjusted based on the determined crystal parameter (e.g., height, mass, shape, growth rate, doping level, crystal stress, one or more optical properties, uniformity, etc.). In some embodiments, a machine-learning model may be utilized to determine optimal process parameters to be adjusted and how much to adjust each process parameter. In addition, example aspects of the present disclosure are directed to systems for implementing the methods discussed herein. Specifically, example aspects of the present disclosure are directed to crystal growth systems for growing silicon carbide crystalline materials and providing in-situ monitoring of crystal growth processes within a growth chamber of the crystal growth system. Accordingly, an example crystal growth system may include a seed holder, a crucible, a source material, one or more heating elements, and a sensor for measuring a physical property of the crystalline material within the crystal growth chamber.

Various sensors may be utilized within the crystal growth system. For instance, in some embodiments, the sensor may be an imaging device. The imaging device may include an imaging sensor proximate to an outer surface of the crystal growth chamber and may face toward the crystal growth chamber. The imaging device may capture one or more images of the crystalline material within the crystal growth chamber and, in some instances, may capture one or more images during each of a plurality of growth segments in the crystal growth process. Additionally, in some embodiments, the imaging device may be actuatable between a first plane and a second plane to obtain various data associated with the crystalline material. In some embodiments the imaging device may be an x-ray imaging device.

As another example, in some embodiments, the sensor may be a sensing coil. The sensing coil may be proximate to the outer surface of the crystal growth chamber and may be disposed around the growth surface of the crystal growth chamber. The sensing coil may generate inductive current data as the measured data to determine a crystal parameter (e.g., height, mass, shape, growth rate, doping level, crystal stress, one or more optical properties, uniformity, etc.).

In some embodiments, an example crystal growth system may include a first imaging detector and a second imaging detector. The imaging detectors may be positioned proximate to the outer surface of the crystal growth chamber and opposite the sensor of the crystal growth system. In some of these embodiments, the imaging sensor may be actuatable between the first imaging detector and the second imaging detector. More imaging detectors (e.g. three imaging detectors, four imaging detectors, five imaging detectors, may be used without deviating from the scope of the present disclosure).

Example aspects of the present disclosure can provide a number of technical effects and benefits, including improvements to semiconductor crystalline material growth technology. Aspects of the present disclosure are directed to reducing semiconductor crystal parameter variation, thus improving general crystal quality and yield. With more consistency (e.g., less variation) in crystal parameters (e.g., height, mass, shape, growth rate, doping level, crystal stress, one or more optical properties, uniformity, etc.), less material is wasted through scrapping during the crystal growth process. As an added result, more usable product(s) may be generated from the same amount of starting material. Additionally, example aspects of the present disclosure may be directed toward crystal growth system maintenance and error reduction. For instance, in monitoring crystal parameters (e.g., height, mass, shape, growth rate, doping level, crystal stress, one or more optical properties, uniformity, etc.) using measured physical data, drastic variations between the measured data and expected yield may enable earlier detection of potential miscalibrations or faults within crystal growth systems and related sensors. In turn, this can reduce the amount of material wasted due to scrap from poorly calibrated or defective machinery.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, typical embodiments are described and, although specific terms are employed, they are used in a generic and descriptive sense only and not for purposes of limitation of the scope set forth in the following claims.

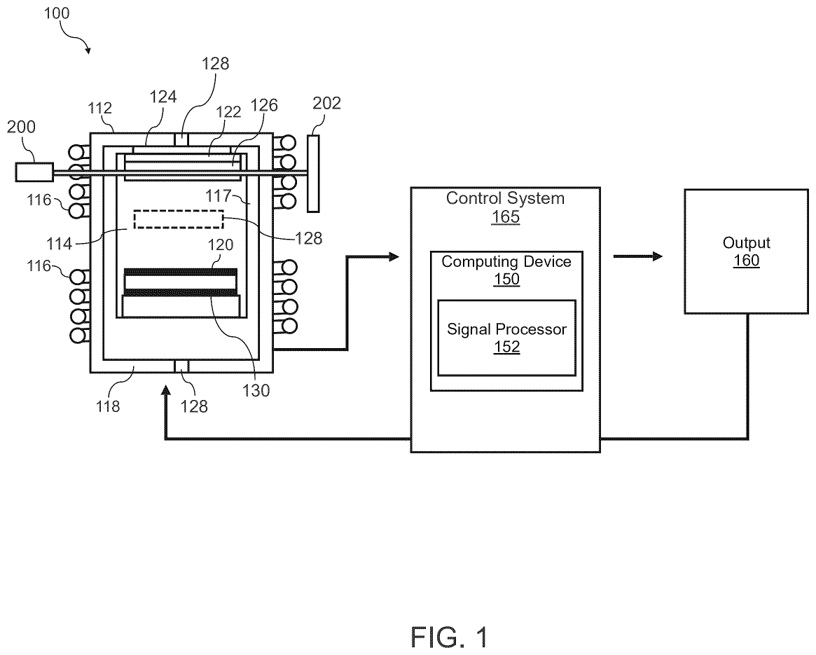

FIG. 1 depicts a system 100 for real-time monitoring of crystal growth processes according to example aspects of the present disclosure. Aspects of the system 100 are directed to adjusting one or more process parameters (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) of the crystal growth process in real time based on measured physical properties of the crystalline material during crystal growth. The system 100 includes the crystal growth system 112, computing device providing output 160, and a control system 155. The crystal growth system 112 includes a crucible 118 defining a crystal growth chamber 114. Insulation 117 (e.g., graphite insulation) may be in the crystal growth chamber 114. The crystal growth system 112 may include one or more heating elements 116 (e.g., induction coils and/or resistive heating elements) around the crucible 118 and growth chamber 114. In some examples, the heating elements 116 may include a combination of resistive and inductive heaters and/or may be used to create one or more thermal zones. The heating elements 116 may impart thermal gradients within the crystal growth chamber 114 to cause vapor transport from a silicon carbide source material 120 to a seed crystal 122 to grow crystalline material on the seed crystal 122, forming a crystalline material 126 (e.g., in a PVT process). In some embodiments, the heating elements 116 may be arranged to generate different thermal zones within crystal growth chamber 114 (e.g., with overlapping coils, more dense coils, etc.). The crystal growth chamber 114 may include a seed holder 124 and a source material holder 130. In some embodiments, the source material holder 130 may include the source material 120 to grow the crystalline material 126 (e.g., crystalline material boule). The source material 120 may include a powdered source material, solid source material, or any other suitable silicon, carbon, and/or silicon carbide source material for growing a silicon carbide crystalline material on the seed crystal. Example silicon carbide source materials are disclosed in U.S. application Ser. No. 18/963,103, filed on Nov. 27, 2024, and in U.S. application Ser. No. 18/963,117, filed on Nov. 27, 2024, both of which are incorporated herein by reference.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

In some examples, the crystal growth system 112 may include an optional interface structure 115, represented in dashed lines, between the crystalline material 126 and the source material 120. In some examples, the interface structure 115 may include a baffle structure and/or secondary source. Example baffle structures that may be used are disclosed in U.S. patent application Ser. No. 18/962,454, filed on Nov. 27, 2024, which is incorporated herein by reference.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

The interface structure 115 may have one or more apertures or may be made from a porous material to allow for the passage of vapor. In some examples, the interface structure 115 may be a graphite material (e.g., porous graphite, such as porous graphite having a porosity greater than about 40%, such as greater than about 70%, such as about 40% to about 97%, such as about 70% to about 9%7). The interface structure 115 In some examples, the interface structure 115 may be a coated graphite material. Example coatings that may be used are disclosed in U.S. application Ser. No. 18/963,196, filed on Nov. 27, 2024, U.S. application Ser. No. 18/963,136, filed on Nov. 27, 2024, and U.S. application Ser. No. 18/963,240, filed on Nov. 27, 2024, which are incorporated herein by reference.

In some embodiments, a coating may include metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C.). The thickness of the final coating may be able to be controlled, for example by varying the concentration of metal particles in the coating and by varying the deposition volume of the coating onto the surface or part.

In some embodiments, a coating be created by applying an organometallic compound to at least one surface of a structure, wherein the at least one surface of the structure contains carbon or an oxide, curing the organometallic compound on the at least one surface of the structure; and heating the organometallic compound on the at least one surface of the structure such that the metal carbide coating is formed on the at least one surface of the structure, wherein the organometallic compound includes a central metal atom; and ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum. In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some examples, furanic ultra high temperatures adhesives (UHTAs) may be used as a binder in a paint that converts to a coating, such as solution processable ceramic coatings (e.g., TaC, NbC, SiC, etc.) or a non-ceramic coating (e.g., glassy carbon coatings). Certain furan functionalized compound can be used as ultra-high temperature adhesives. The chemistry of furan rings allows a broad range of furan-containing polymeric, molecular, or inorganic-organic hybrid materials that can function as UHTAs. Examples of such materials incorporating the furan heterocycle as a structural unit include: furanic polymers and resins; furanic molecules and macromolecules; furanic rigid network solids; and furan functionalized micromaterials or nanomaterials.

With the proper material design, the furanic constituents would allow these compounds to participate in crosslinking (curing) through Diels-Alder cycloaddition and the formation of a bonded glassy carbon (BGC) network. Crosslinking, which forms a three-dimensional polymeric network, can be initiated through the application of chemical, photochemical, thermal, mechanical, or electrical energy. Once cured, these materials become structurally robust solids that bind strongly to a substrate. As these cured solids are pyrolized, the furan constituents undergo ring opening and forming reactive alkene fragments (CH2═CH2) and radicals which drive the formation of and condensation of polyaromatic cores resulting in a BGC network, which results in an UHTA.

The adhesion of furanic UHTAs may be further improved through the incorporation of a filler material. Use of such filler materials with UHTAs as a binding agent may be referred to as a “brick and mortar” model. Such filler materials may improve the adhesive properties of the UHTA by mechanical reinforcement. During pyrolysis of the furanic UHTA, the filler or any products generated by the chemical change of the filler may be incorporated into the network as a structural unit and mechanically strengthen the resulting bonded glassy carbon network through covalent bonding and/or strong non-covalent interactions. Such filler materials may also improve the adhesive properties of the UHTA by promoting carbon condensation. During pyrolysis of the furanic UHTA, the filler or any products generated by the chemical change of the filler may aid in the condensation of intermediate polyaromatic cores through covalent bonding and/or strong non-covalent interactions. By contributing to the condensation, a denser bonded glassy carbon network may be produced.

In some embodiments, filler materials used with furanic UHTAs may be active or may be passive. Active fillers undergo a chemical change (e.g., thermal decomposition, reduction, oxidation, solid state synthesis, etc.) into one or more products during the pyrolysis of the UHTA. Active fillers may also change aggregate state or are subject to diffusion before or during undergoing a chemical change. Passive fillers can form covalent bonds or participate in strong non-covalent interactions with the bonded glassy carbon network, but do not undergo further chemical reactions during the pyrolysis of the UHTA. Passive fillers can be impermeable or can be porous, allowing the furanic UHTA to penetrate into the material. In the case of a porous filler, the bonded glassy carbon network may form inside and outside the filler material during the pyrolysis of the UHTA. Passive fillers may participate in sintering, recrystallization, surface or bulk diffusion processes during temperature exposure. Either active or passive fillers may also create voids or porosity during temperature treatments. For example, fillers may decompose or evaporate to create voids in the UHTA. . The interface structure 115 may extend all the way across a width or diameter of the growth chamber and/or all the way across the flux path. The interface structure 115 may be included in any of the crystal growth systems provided herein without deviating from the scope of the present disclosure.

In some examples, the crystal growth system 112 may include one or more actuators 128. The actuators 128 may be configured to impart translational and/or rotational movement to one or more components of the crystal growth system 112, such as the seed holder 124 and crystalline material 126, the source material 120, the insulation 117, the heating elements 116, the interface structure 115, the crucible 118, and/or other elements. The actuator(s) 128 may be include any suitable type of actuator, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator), rotary actuator (e.g., screwing arrangement) and/or other suitable actuator.

Those of ordinary skill in the art, using the disclosure provided herein, will understand that any type of actuator may be used to move components without deviating from the scope of the present disclosure. The actuator(s) 128 may be operated independently of each other to cause relative positioning of components relative to other components. For instance, in some embodiments, the source 120 may be rotated independently of the crystalline material 126. In some embodiments, one or more actuator(s) 128 may be operable to move the crystalline material 126 (e.g., the growth face of the crystalline material 126) to different vertical positions relative to the source material 120 during a crystal growth process. For instance, the one or more actuator(s) 128 may move the crystalline material 126 and/or the source material 120 such that there is a first transport distance between the crystalline material 126 and the source material 120 for a first process period. One or more actuators may move the crystalline material 126 and/or the source material 120 such that there is a second transport distance (e.g., different from the first transport distance) between the crystalline material 126 and the source material 120 for a second process period.

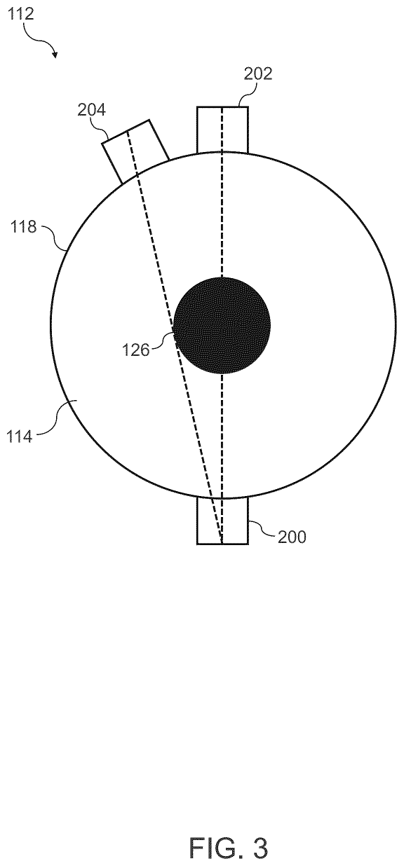

In some embodiments, the crystal growth system 112 may additionally include one or more sensors, such as the imaging device 200 and imaging detector(s) 202. The sensors may be used to measure physical properties of the crystalline material boule 126. As an example, the imaging device 200 may be an x-ray imaging device. The imaging device 200 may include an imaging sensor proximate to the outer surface of the crystal growth chamber 114 and, as depicted, may be directed toward the imaging detector(s) 202. The crystalline material 126 may be between the imaging device 200 and the imaging detector(s) 202. In some embodiments, the imaging device 200 may be used to obtain measured physical data for the crystalline material boule, from the crystal growth system 112, associated with the crystalline material 126. Although not depicted, the crystal growth system 112 may additionally include a second imaging detector which will be discussed in greater detail with reference to FIG. 3.

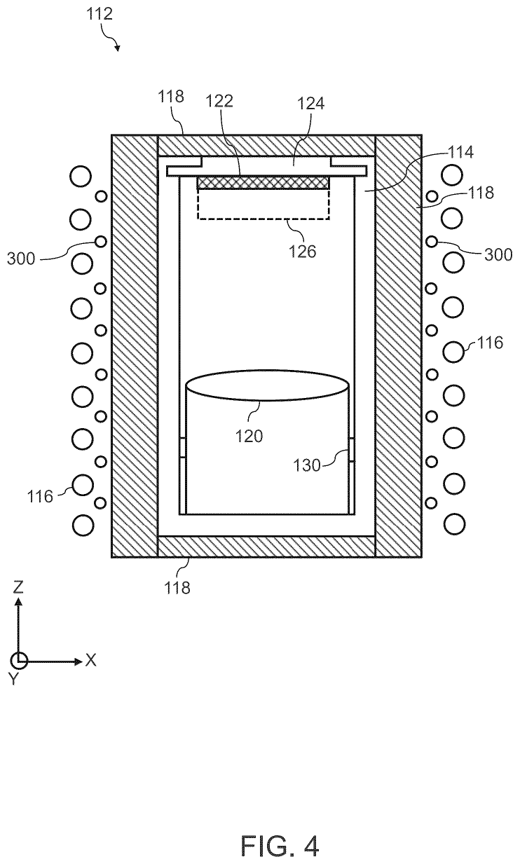

In an additional embodiment, although not depicted in FIG. 1, the process monitoring sensors may include an inductive sensing coil. The inductive sensing coil may be about the crystal growth chamber 114 and provide measured inductive current data to the computing device 150. These embodiments will be discussed in greater detail with reference to FIG. 4.

Various measured data from the crystal growth system 112 may be provided to the computing device 150, which may include a signal processor 152. The computing device 150 may include or be a part of, for instance, a controller or a control system 165 for controlling aspects of the crystal growth system 112. The computing device 150 may include one or more microcontrollers, microprocessors, or other devices. For instance, as examples, one or more images, x-ray image data, ultrasound data, acoustic data, laser data, optical data, and/or inductive current data may be provided to the computing device 150 as the measured data from the crystal growth system 112. In some embodiments, the measured data may be a two-dimensional representation of three-dimensional data associated with the crystalline material 126.

In some embodiments, the measured data obtained from the crystal growth system 112 may be provided to the computing device 150 to generate the output 160. For instance, one or more images, such as x-ray images, from the crystal growth system may be provided to the computing device 150 which, in turn, may determine a crystal parameter (e.g., height, mass, shape, growth rate, doping level, stress or strain, one or more optical properties, uniformity, etc.) of the crystalline material 126 based on the measured data. The crystal parameter may be determined based on a physical property at the time of measurement (e.g., a current mass, a current height, a current diameter, a thermal conductivity, a crystallographic structure, growth face morphology, purity or incorporation of impurities, a defect density, a current measurement indicative of mechanical behavior, such as elastic and plastic properties) of the crystalline material 126. As previously discussed, the output 160 may include a crystal parameter (e.g., height, mass, shape, growth rate, doping level, stress or strain, one or more optical properties, uniformity, etc.) of the crystalline material 126.

In some embodiments, the output 160 may be used by the system 100 (e.g., by a control system 165) to adjust one or more process parameters (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) of a crystal growth process, for instance, in real time. The control system 165 may include one or more control devices that are able to control components of the crystal growth system 112 to implement the adjustment to the one or more process parameters.

For instance, as an example, the computing device 150 may obtain measured data associated with a physical property of the crystalline material 126 and determine the output 160. The output 160 may be used by the control system 165 to adjust or control one or more process parameters associated with the crystal growth system 112. Various process parameters may be adjusted based on the output 160. For instance, as examples, temperature, pressure, vapor pressure, coolant flow rate, vapor flux, growth segment duration, heating element position, crucible position, crucible position relative to heating element position, crystal position, source position, rotation of the crystal, and/or any of the controllable operation parameters may, either alone or in combination, be adjusted based on the output 160. In some embodiments, a machine-learning model may be utilized to determine optimal process parameters to be adjusted and how much to adjust each process parameter.

In some embodiments, a crystal growth process may include a plurality of crystal growth segments. For each of the crystal growth segments, measured data indicative of a physical property of the crystalline material may be provided to the computing device 150. A crystal parameter may be determined for each crystal growth segment. Accordingly, the system 100 may adjust one or more process parameters (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) for each of the crystal growth segments. In some embodiments, a machine-learning model may be utilized to determine optimal process parameters to be adjusted and how much to adjust each process parameter.

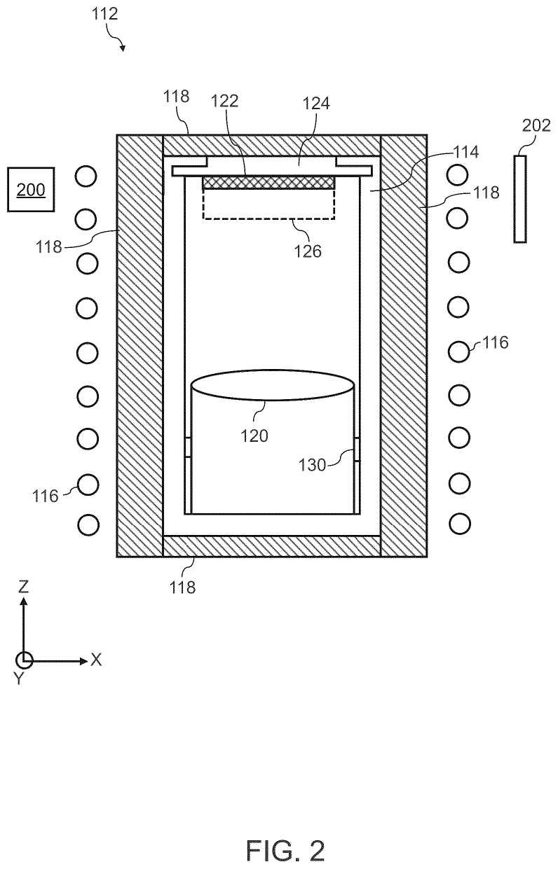

FIG. 2 depicts a cross-sectional schematic diagram of an example crystal growth system 112 for use in a crystal growth process according to example aspects of the present disclosure. The crystal growth system 112 may conduct a crystal growth process. During such process, the crystalline material 126 (e.g., a crystalline material boule) may be grown on the seed material 122 held by the seed holder 124. The crystalline material 126 may be grown by providing thermal gradients within the crystal growth chamber 114 to cause vapor transport from the silicon carbide source material 120 to the seed crystal 122.

As discussed with reference to FIG. 2, in some embodiments, measured data indicative of the crystalline material 126 within the crystal growth system 112 may be obtained during a crystal growth process. In some embodiments, the crystal growth process may include a plurality of growth segments. Each growth segment may be associated with one or more process parameters (e.g., temperature, pressure, vapor pressure, coolant flow rate, vapor flux, growth segment duration, heating element position, crucible position, crucible position relative to heating element position, crystal position, source position, rotation of the crystal, and/or any of the controllable operation parameters) for a process period. In some embodiments, measured data associated with a physical property the crystalline material 126 during the first growth segment may be obtained to determine a crystal parameter of the crystalline material 126 during that growth segment. In some embodiments, measured data associated with the crystalline material 126 during a preceding growth segment may be obtained to determine a crystal parameter of the crystalline material 126 during a future growth segment. Based on the crystal parameter, one or more process parameters associated with the crystal growth system 112 may be adjusted. As examples, temperature, pressure, vapor pressure, coolant flow rate, vapor flux, growth segment duration, heating element position, crucible position, crucible position relative to heating element position, crystal position, source position, rotation of the crystal, and/or any of the controllable operation parameters, or other process parameters may be adjusted during a particular growth segment or, in some embodiments, in a future growth segment. For instance, measured data associated with the crystalline material 126 may be obtained during a second growth segment and one or more process parameters associated with the crystal growth system 112 may be adjusted for a future third, fourth, fifth, etc. growth segment.

FIG. 3 depicts a top-down view of a crystal growth system 112 according to example aspects of the present disclosure. As discussed with reference to FIG. 2, the crystal growth system 112 may include an imaging device 200 and an imaging detector(s) 202. The imaging device 200 may include an imaging sensor facing the crystal growth chamber 114 and proximate an outer surface of the crystal growth chamber 114 (e.g., proximate the outer surface of the crucible 118). Additionally, in some embodiments, the crystal growth system 112 may include a second imaging detector 204. The second imaging detector 204, like the imaging detector 202 may include an imaging surface proximate to the outer surface of the crystal growth chamber 114. In some embodiments, the imaging device may be actuatable between the imaging detector 202 and the second imaging detector 204. In this manner, the imaging device 200 may be able to obtain measured data of the crystalline material 126 from a first imaging plane via the imaging detector 202 and a second imagining plane via the second imaging detector 204. In some embodiments, by obtaining measured data across various planes, a three-dimensional representation of the crystalline material 126 may be developed.

FIG. 4A depicts a cross-sectional diagram of an example crystal growth system 112 according to example aspects of the present disclosure. The crystal growth system 112 is similar to the system 112 shown in FIG. 2 but includes one or more inductive sensing coils 300 as process monitoring sensors. The one or more sensing coils 300 (e.g., graphitic coils) may surround at least a portion of the crystal growth chamber 114, proximate to an outer surface of the crystal growth chamber 114. In some embodiments, the one or more inductive sensing coils may be used to determine a crystal parameter (e.g., height, mass, shape, growth rate, doping level, stress or strain, one or more optical properties, uniformity, etc.) of the crystalline material 126. For instance, the one or more inductive sensing coils 300 may generate inductive current data indicative of a physical property of the crystalline material 126. For instance, inductive sensing approaches may be used to determine, for instance, the mass and/or height of the crystalline material 126 based on the reactance of the coil 300.

FIG. 4 depicts the inductive sensing coil 300 as being separate from the heating element 116. In some embodiments, the inductive sensing coil 300 may be the same as the heating element 116. For instance, the heating element 116 may be an inductive heating coil. Inductive sensing approaches may be used to determine, for instance, the mass and/or height of the crystalline material 126 based on the reactance of the heating element 116 (e.g., a coil).

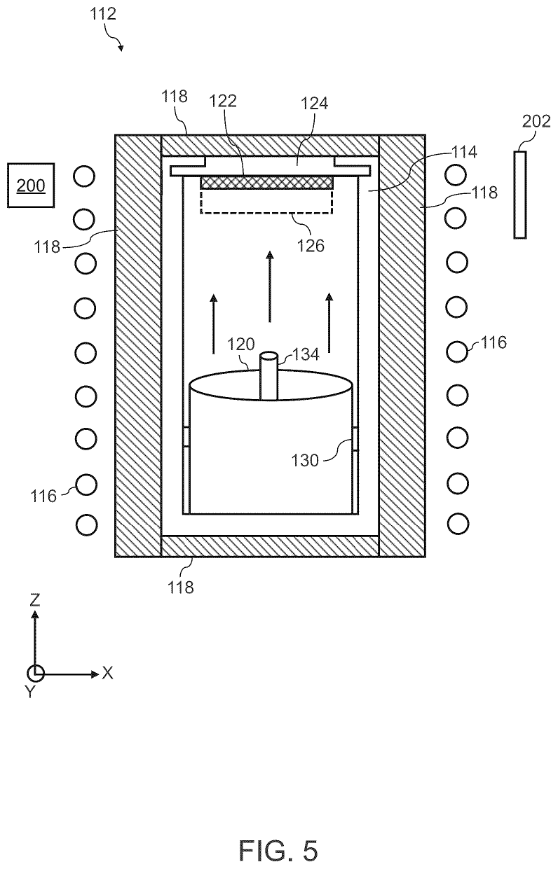

FIG. 5 depicts a cross-sectional diagram of an example crystal growth system 112 according to example aspects of the present disclosure. The crystal growth system 112 may be similar to that shown in FIG. 2 but also includes an inlet 134 for introducing a dopant (e.g., N2) to the crystal growth chamber 114. The inlet 134, may be, for example, a tube, pipe, vent, or the like. In some embodiments, the source material 120 may surround the inlet 134. For example, in some embodiments, the solid shaped source material structure may include a channel through which the inlet 134 is provided. In other embodiments, the solid shaped source material structure may include a plurality of subcomponents (attached or detached) which surround the inlet 134. The inlet 134 may be connected to a dopant-containing gas source (not shown) and configured to introduce the dopant-containing gas to the crystal growth chamber 114. An example of a dopant-containing gas is nitrogen. In some embodiments, adjusting one or more process parameters associated with the crystal growth process may include varying an amount or flow rate of the dopant into the crystal growth chamber 114 via the inlet 134.

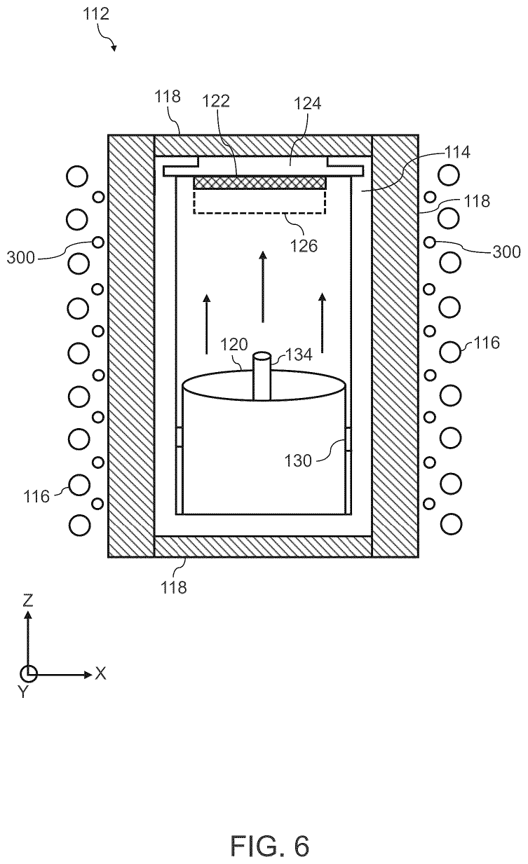

FIG. 6 depicts a cross-sectional diagram of an example crystal growth system 112 according to example aspects of the present disclosure. The crystal growth system 112 is similar to that shown in FIG. 5 but includes an inductive sensing coils 300 instead of the imaging device 200 and imaging detector(s) 202. The plurality of inductive sensing coils 300 may surround at least a portion of the crystal growth chamber 114 proximate to an outer surface of the crystal growth chamber 114. In some embodiments, the plurality of inductive sensing coils 300 may be used to determine a crystal parameter (e.g., height, mass, shape, growth rate, doping level, stress or strain, one or more optical properties, uniformity, etc.) of the crystalline material 126. For instance, the plurality of inductive sensing coils 300 may provide inductive current data indicative of a height or shape of the crystalline material 126. For instance, the one or more inductive sensing coils 300 may generate inductive current data indicative of a physical property of the crystalline material 126. Inductive sensing approaches may be used to determine, for instance, the current mass and/or height of the crystalline material 126 based on the reactance of the coil 300.

FIG. 6 depicts the inductive sensing coil 300 as being separate from the heating element 116. In some embodiments, the inductive sensing coil 300 may be the same as the heating element 116. For instance, the heating element 116 may be an inductive heating coil. Inductive sensing approaches may be used to determine, for instance, the mass and/or height of the crystalline material boule 126 based on the reactance of the heating element 116 (e.g., a coil).

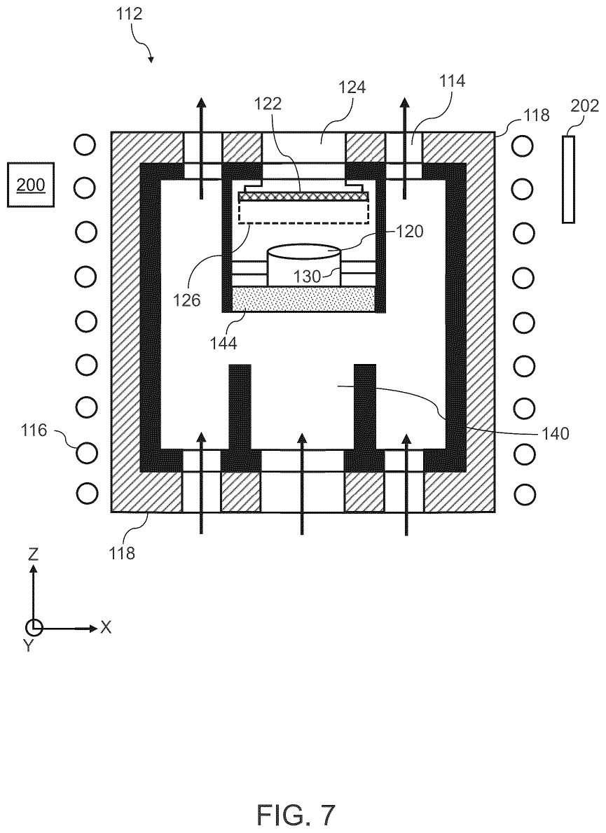

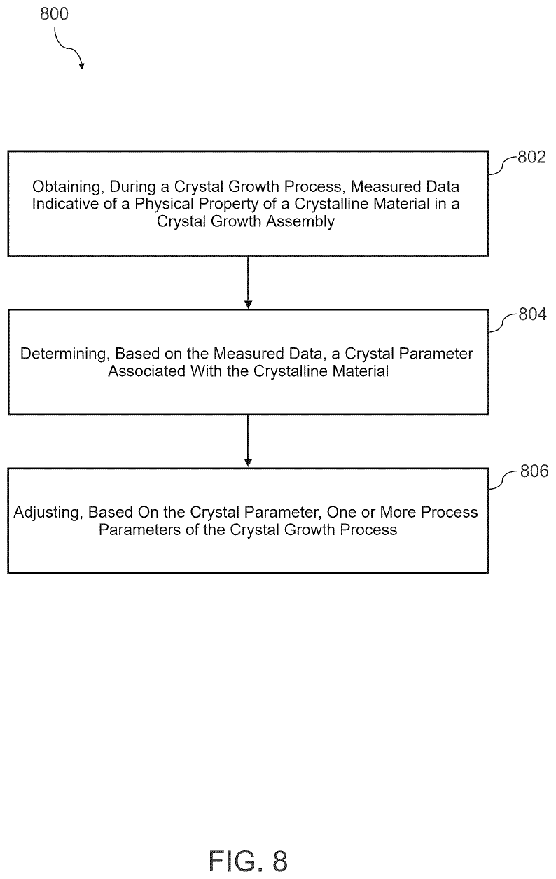

FIG. 7 depicts an example embodiment of the crystal growth system 112 as a continuous feed PVT system according to example aspects of the present disclosure. In some embodiments, the crystal growth system 112 may be a continuous feed PVT (CF-PVT) system. In the CF-PVT system, the crystal growth chamber 114 may include an upper chamber 138 and a lower chamber 140. The upper chamber 138 may include the solid source material 120 and the seed material 122. The upper chamber 138 may be separated from the lower chamber 140 by a foamed structure 144. The foamed structure 144 may be formed, for example, from a gas-permeable graphite foam. The solid source material 120 may be placed on the foamed structure 144 within the upper chamber. A gaseous silicon source (e.g., trimethylsilane diluted in argon) may be supplied to the lower chamber. As the gaseous silicon source flows through the foamed structure 144, it may react with a carbon source within the foamed structure 144 (e.g., graphite) to form silicon carbide. The CF-PVT system combines the PVT process for the growth of single crystals and high-temperature chemical vapor deposition (HTCVD) process for the in-situ formation and continuous feeding of high purity polycrystalline source. The CF-PVT system may be particularly useful for growing 3C silicon carbide. In some embodiments, the crystal growth system may include the imaging device 200 and the imaging detector(s) 202. Measured data may be obtained from the CF-PVT system, such as via the imaging device 200, and used to determine a crystal growth height of the crystalline material boule 126 (e.g., crystalline material) and adjust one or more process parameters of the CF-PVT system based on the crystal growth height, in accordance with aspects of the present disclosure. While not depicted, it should be appreciated that any sensing apparatus discussed herein with reference to crystal growth systems, such as the crystal growth system 112 may be utilized in the CF-PVT system depicted in FIG. 7 including, but not limited to, a plurality of inductive sensing coils. FIG. 8 depicts a block diagram of an example method 800 according to example aspects of the present disclosure. FIG. 8 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 802, the method 800 includes obtaining, during a crystal growth process, measured data indicative of a physical property of a crystalline material in a crystal growth system. As examples, the physical property may include one or more of a current physical dimension such as height or diameter, a current mass, a thermal conductivity, a crystallographic structure, growth face morphology, purity or incorporation of impurities, a defect density, or other physical property associated with the crystalline material. In some embodiments, the crystalline material may be silicon carbide, such as a 4H, 6H, 15R, 3C or other polytype of crystalline silicon carbide. Additionally, various types of measured data may be obtained. As examples, the measured data may be one or more images, x-ray image data, ultrasound data, acoustic data, laser data, optical data, or inductive current data. In some embodiments, the measured data may include a two-dimensional representation of three-dimensional data associated with the crystalline material.

In some embodiments, the crystal growth system may include a plurality of imaging detectors. The imaging detectors may, in some instances, each include an imaging surface proximate to an outer surface of the crystal growth system. Additionally, in some embodiments, the crystal growth system may include an imaging device that obtains the measured data during the crystal growth process. The imaging device may be an x-ray imaging device. In some instances, the imaging device may be actuatable between the first imaging detector and the second imaging detector. The crystalline material may be placed between the imaging device and the first and second imaging detector.

Additionally, or alternatively, in some embodiments, the crystal growth system includes a sensing coil that obtains the measured data during the crystal growth process. The crystalline material may be placed within the sensing coil, and, in some instances, the measured data may include inductive current data.

At 804, the method 800 includes determining, based on the measured data, a crystal parameter associated with the crystalline material. Various parameters may be determined relating to the crystalline material. For instance, the crystal parameter may be one or more of a height, mass, shape, growth rate, doping level, stress or strain, one or more optical properties, uniformity, etc. of the crystalline material. For instance, in some embodiments, the measured data may be used to determine the crystal parameter of growth height of the crystalline material to be grown during a crystal growth process.

At 806, the method 800 includes adjusting, based on the crystal parameter, one or more process parameters of the crystal growth process. Various process parameters may be adjusted. For instance, as examples, temperature, pressure, vapor pressure, coolant flow rate, vapor flux, growth segment duration, heating element position, crucible position, crucible position relative to heating element position, crystal position, source position, rotation of the crystal, and/or any of the controllable operation parameters may be adjusted. In some embodiments, a machine-learning model may be utilized to determine optimal process parameters to be adjusted and how much to adjust each process parameter.

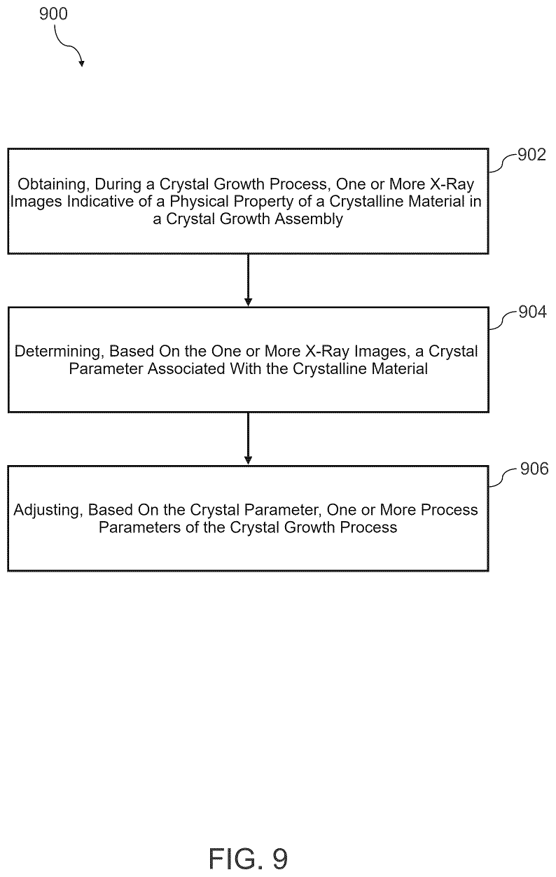

FIG. 9 depicts a block diagram of an example method 900 according to example aspects of the present disclosure. FIG. 9 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 902, the method 900 includes obtaining, during a crystal growth process, one or more x-ray images indicative of a physical property of a crystalline material in a crystal growth system. As examples, the physical property may include one or more of a current physical dimension such as height or diameter, a current mass, a thermal conductivity, a crystallographic structure, growth face morphology, purity or incorporation of impurities, a defect density, or other physical property associated with the crystalline material. In some embodiments, the crystalline material may be silicon carbide, such as 4H, 6H, 15R, 3C or other polytype of crystalline silicon carbide. The crystal growth process may include a plurality of growth segments, and the one or more x-ray images may be obtained during each of the plurality of growth segments. Additionally, various types of x-ray images may be obtained. In some embodiments, the x-ray images may be two-dimensional images and/or three-dimensional images.

In some embodiments, the crystal growth system may include a plurality of imaging detectors. The imaging detectors may each include an imaging surface proximate to an outer surface of the crystal growth system. Additionally, in some embodiments, the crystal growth system may include an imaging device that obtains the one or more x-ray images during the crystal growth process. In some instances, the imaging device may be actuatable between the first imaging detector and the second imaging detector. The crystalline material may be placed between the imaging device and the first and second imaging detector.

At 904, the method 900 includes determining, based on the one or more x-ray images, a crystal parameter associated with the crystalline material. Various parameters may be determined relating to the crystalline material. For instance, the crystal parameter may be one or more of a height, mass, shape, growth rate, doping level, stress or strain, one or more optical properties, uniformity, etc. of the crystalline material. In some embodiments, the one or more x-ray images may be used to determine the crystal parameter of growth height of the crystalline material to be grown during a crystal growth process. The growth height may be a distance from the base of a seed holder within the crystal growth system to a farther point of the edge of a growth surface of the crystalline material.

At 906, the method 900 includes adjusting, based on the crystal parameter, one or more process parameters of the crystal growth process. Various process parameters may be adjusted. For instance, as examples, temperature, pressure, vapor pressure, coolant flow rate, vapor flux, growth segment duration, heating element position, crucible position, crucible position relative to heating element position, crystal position, source position, rotation of the crystal, and/or any of the controllable operation parameters may be adjusted. In some embodiments, a machine-learning model may be utilized to determine optimal process parameters to be adjusted and how much to adjust each process parameter.

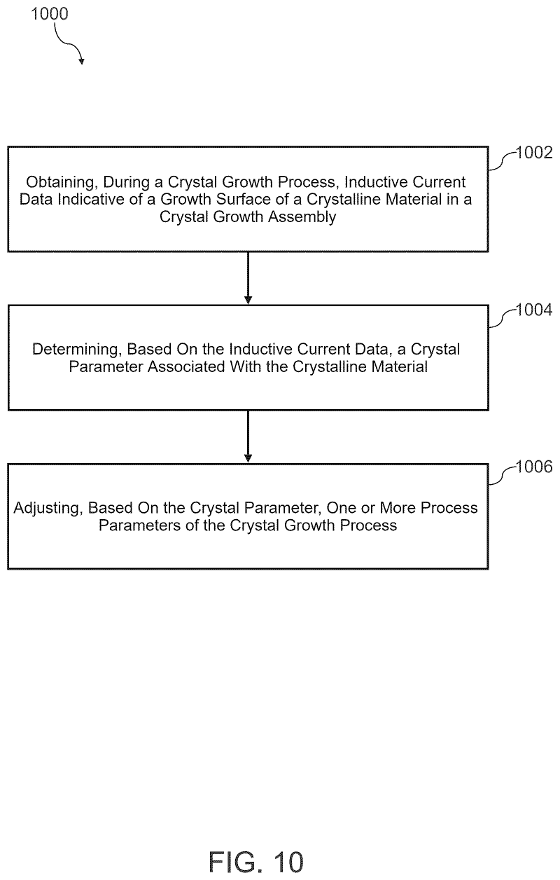

FIG. 10 depicts a block diagram of an example method 1000 according to example aspects of the present disclosure. FIG. 10 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 1002, the method 1000 includes obtaining, during a crystal growth process, inductive current data indicative of a physical property of a crystalline material in a crystal growth system. As examples, the physical property may include one or more of a current physical dimension such as height or diameter, a current mass, a thermal conductivity, a crystallographic structure, growth face morphology, purity or incorporation of impurities, a defect density, or other physical property associated with the crystalline material. In some instances, the crystalline material may be silicon carbide, such as 4H, 6H, 15R, 3C or other polytype of crystalline silicon carbide. In some embodiments, the crystal growth system may include an inductive sensing coil. The inductive sensing coil may obtain the inductive current data from the crystal growth process. To obtain the inductive current data, the crystalline material may be placed within the sensing coil. In some embodiments, the crystal growth process may include a plurality of growth segments, and the inductive current data may be obtained during each of the plurality of growth segments.

At 1004, the method 1000 includes determining, based on the inductive current data, a crystal parameter associated with the crystalline material. Various parameters may be determined relating to the crystalline material. For instance, the crystal parameter may be one or more of a height, mass, shape, growth rate, doping level, stress or strain, one or more optical properties, uniformity, etc. of the crystalline material. In some embodiments, the inductive current data may be used to determine the crystal parameter of growth height of the crystalline material during a crystal growth process. The growth height may be a distance from the base of a seed holder within the crystal growth system to a farther point of the edge of a growth surface of the crystalline material.

At 1006, the method 1000 includes adjusting, based on the crystal parameter, one or more process parameters of the crystal growth process. Various process parameters may be adjusted. For instance, as examples, one or more of a temperature, pressure, vapor pressure, coolant flow rate, vapor flux, growth segment duration, heating element position, crucible position, crucible position relative to heating element position, crystal position, source position, rotation of the crystal, and/or any of the controllable operation parameters may be adjusted. In some embodiments, a machine-learning model may be utilized to determine optimal process parameters to be adjusted and how much to adjust each process parameter.

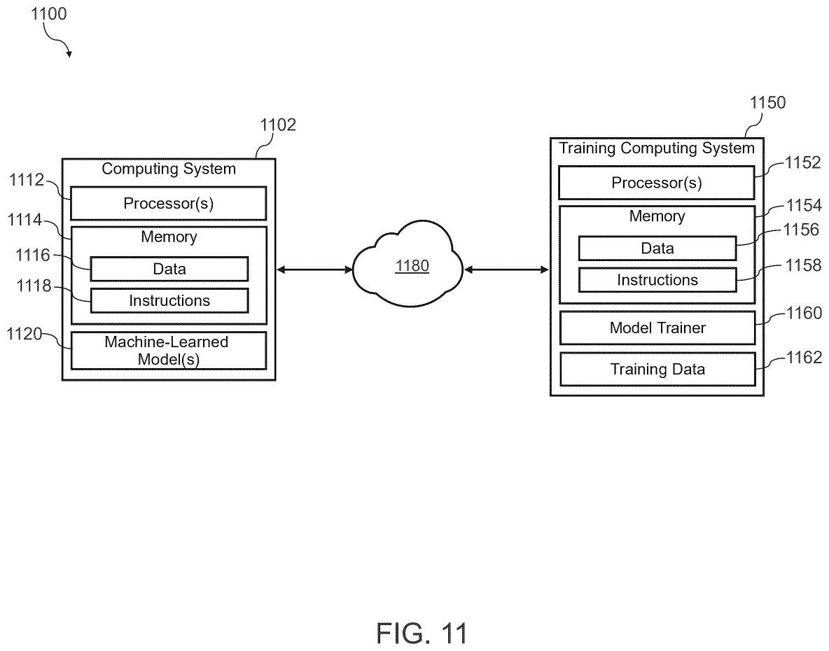

FIG. 11 depicts a block diagram of an example computing system 1100 according to example aspects of the present disclosure. The example computing system 1100 may be used to implement systems and methods according to example embodiments of the present disclosure. The system 1100 includes a computing system 1102 and a training computing system 1150 that are communicatively coupled over a network 1180.

The computing system 1102 may include any type of computing device (e.g., classical and/or quantum computing device). The computing system 1102 includes one or more processors 1112 (e.g., processing circuitry) and a memory 1114. The one or more processors 1112 may be any suitable processing device (e.g., a processor core, a microprocessor, CPU, GPU, an ASIC, a FPGA, a controller, a microcontroller, etc.) and may be one processor or a plurality of processors that are operatively connected. The memory 1114 may include one or more non-transitory computer-readable storage mediums, such as RAM, ROM, EEPROM, EPROM, flash memory devices, magnetic disks, etc., and combinations thereof. The memory 1114 may store data 1116 (e.g., parameters, input data, etc.) and instructions 1118 which are executed by the processor 1112 to cause the computing system 1102 to perform operations. In some implementations, the computing system 1102 may store or include one or more machine-learned models 1120 (e.g., autoencoders, machine-learned encoding models, etc.) as described herein.

The computing system 1102 may train the machine-learned model(s) 1120 via interaction with the training computing system 1150 that is communicatively coupled over the network 1180. The training computing system 1150 may be separate from the computing system 1102 or may be a portion of the computing system 1102.

The training computing system 1150 includes one or more processors 1152 and a memory 1154. The one or more processors 1152 may be any suitable processing device (e.g., a processor core, a microprocessor, CPU, GPU, an ASIC, a FPGA, a controller, a microcontroller, etc.) and may be one processor or a plurality of processors that are operatively connected. The memory 1154 may include one or more non-transitory computer-readable storage mediums, such as RAM, ROM, EEPROM, EPROM, flash memory devices, magnetic disks, etc., and combinations thereof. The memory 1154 may store data 1156 and instructions 1158 which are executed by the processor 1152 to cause the training computing system 1150 to perform operations. In some implementations, the training computing system 1150 includes or is otherwise implemented by one or more server computing devices.

The training computing system 1150 may include a model trainer 1160 that trains the machine-learned model 1120 using various training or learning techniques, such as, for example, backwards propagation of errors. In some implementations, performing backwards propagation of errors may include performing truncated backpropagation through time. The model trainer 1160 may perform a number of generalization techniques (e.g., weight decays, dropouts, etc.) to improve the generalization capability of the models being trained.

In particular, the model trainer 1160 may train the machine-learned model(s) 1120 based on a set of training data 1162. The training data 1162 may include, for example, input data corresponding to a plurality of semiconductor workpieces workpiece images, time series data, tabular data, etc.

The model trainer 1160 includes computer logic utilized to provide desired functionality. The model trainer 1160 may be implemented in hardware, firmware, and/or software controlling a general-purpose processor. For example, in some implementations, the model trainer 1160 includes program files stored on a storage device, loaded into a memory and executed by one or more processors. In other implementations, the model trainer 1160 includes one or more sets of computer-executable instructions that are stored in a tangible computer-readable storage medium such as RAM hard disk or optical or magnetic media.

The network 1180 may be any type of communications network, such as a local area network (e.g., intranet), wide area network (e.g., Internet), or some combination thereof and may include any number of wired or wireless links. In general, communication over the network 1180 may be carried via any type of wired and/or wireless connection, using a wide variety of communication protocols (e.g., TCP/IP, HTTP, SMTP, FTP), encodings or formats (e.g., HTML, XML), and/or protection schemes (e.g., VPN, secure HTTP, SSL).

FIG. 11 illustrates one example computing system 1102 that may be used to implement example aspects of the present disclosure. Other computing systems may be used without deviating from the scope of the present disclosure. For example, in some implementations, the computing system 1102 may include the model trainer 1160 and the training data 1162. In such implementations, the model(s) 1120 may be both trained and used locally at the computing system 1102.

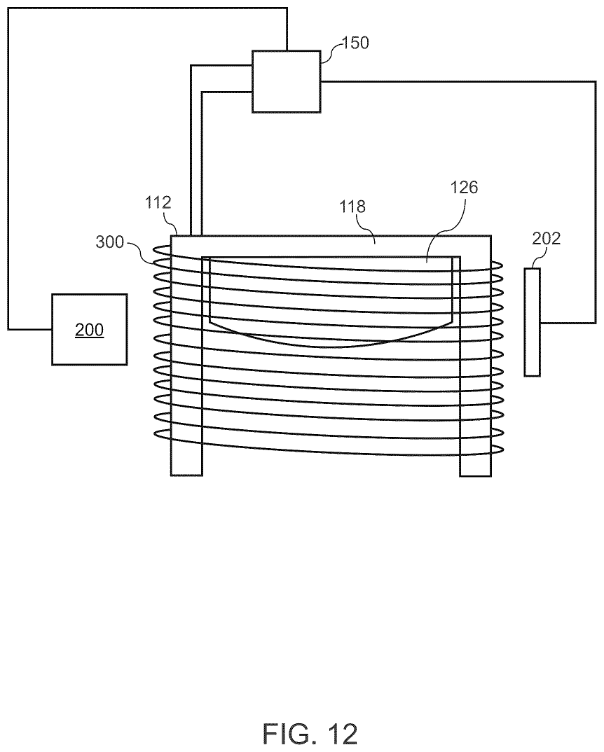

FIG. 12 depicts a cross-sectional diagram of an example crystal growth system 112 according to example aspects of the present disclosure. The crystal growth system 112 includes sensor(s) for determining crystal parameters of the crystal material boule 126.

In some embodiments, the crystal growth system 112 may include multiple types of sensors and select data from a single sensor, or multiple sensors, to determine crystal parameters of the crystal material boule 126. For instance, in some embodiments, the plurality of sensors may include the x-ray imaging device 200 and imaging detector(s) 202 as well as the inductive sensing coil 300. The x-ray imaging device 200 and/or the inductive sensing coil 300 may provide measured data indicative of physical properties of the crystal material boule 126 to the computing device 150. As examples, the x-ray imaging device 200 may provide x-ray image data and the inductive sensing coils 300 may provide inductive current data to the computing device 150. The computing device 150 may, based on the measured data from the sensors, determine one or more crystal parameters associated with the crystal material boule 126.

In some embodiments, a power source may provide current through the inductive sensing coil 300 to generate inductive current data associated with the crystal material boule 126. In these embodiments, as the crystal material boule 126 grows through the coils, the current through the plurality of inductive sensing coils may change, indicating a change in a physical parameter of the crystal material boule 126.

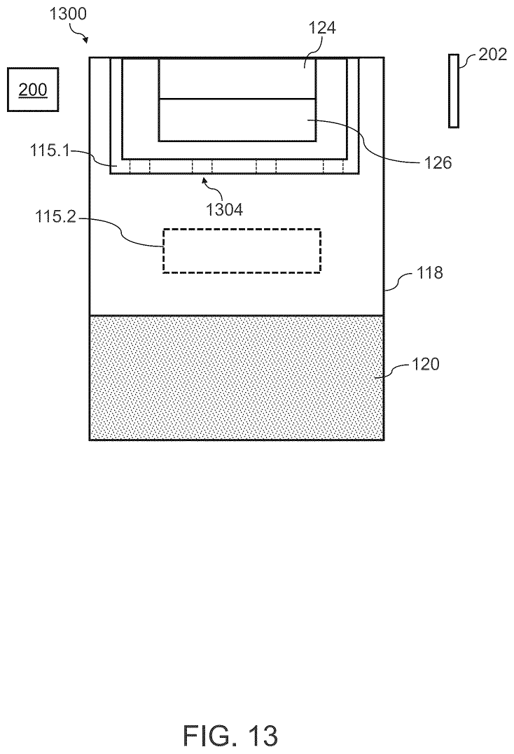

FIG. 13 through 17 depict example crystal growth systems according to example embodiments of the present disclosure. It will be understood that any of the crystal growth systems described herein may include the computing device, the signal processor, the output, the imaging device, or the imaging detector as discussed above.

FIG. 13 depicts an example crystal growth system 1300 according to example embodiments of the present disclosure. In FIG. 13, the crystal growth system 1300 may include the interface structure 115.1, the seed holder 124, the crystalline material 126, the crucible 118, and the source material 120. The interface structure 115.1 may be positioned such that the interface structure 115.1 extends around at least three sides of the crystalline material 126, with the longest dimension located below the crystalline material 126. The interface structure 115.1, in this configuration, may be referred to as a shell structure as it provides a shell around the crystalline material 126. The interface structure 115.1 may be graphite, such as porous graphite. The interface structure 115.1 may include one or more apertures 1304 that assist in the transport of source vapor from the source material 120 to the seed crystal 124. The interface structure 115.1 may include a baffle structure. In some examples, the interface structure 115.1 may or may not include any apertures 1304. The interface structure 115.1 may be porous graphite and may have a porosity of greater than about 70%. The interface structure 115.1 may be positioned such that the interface structure 115.1 extends around at least three sides of the crystalline material 126, with the longest dimension located below the crystalline material 126. The system 1300 may include one or more second interface structure(s) 115.2. The one or more second interface structure(s) 115.2 may be arranged in the vapor transport path from the source material 120 to the crystalline material 126. The one or more second interface structure(s) 115.2 may be graphite, such as porous graphite. The interface structure 115.2 may include a baffle structure. The interface structure 115.2 may include one or more apertures.

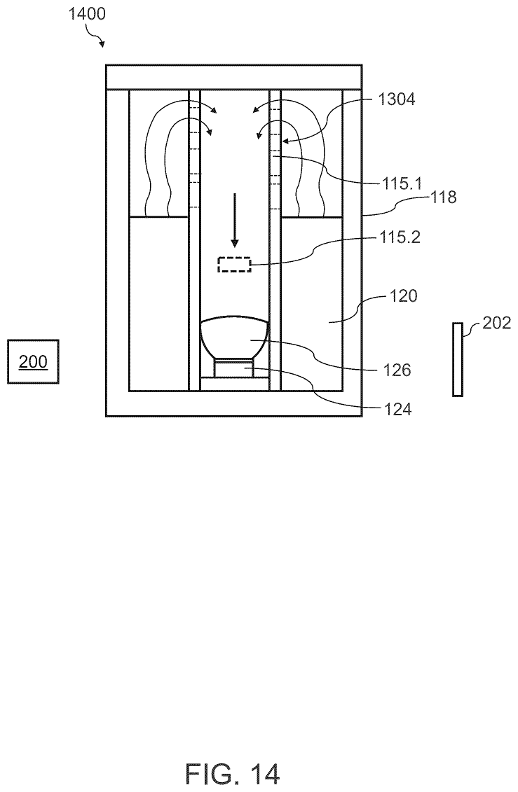

In FIG. 14, the crystal growth system 1400 may include the interface structure 115.1, the seed holder 124, the crystalline material 126, the crucible 118, and the source material 120. The interface structure 115.1 may include a tubular baffle structure. The crystalline material 126 may be within the interface structure 115.1. The interface structure 115.1 may be graphite, such as porous graphite. The interface structure 115.1 may include one or more apertures 1304 that assist in the transport of source vapor from the source material 120 to the seed material 122. The system 1400 may further include one or more second interface structures 115.2. The one or more second interface structures 115.2 may be arranged in the vapor transport path between the source material 120 and the crystalline material 126. Source vapor may be transported through the interface structures 115.1 and 115.2. The one or more second interface structure(s) 115.2 may be graphite, such as porous graphite. The interface structure 115.2 may include a baffle structure. The interface structure 115.2 may include one or more apertures.

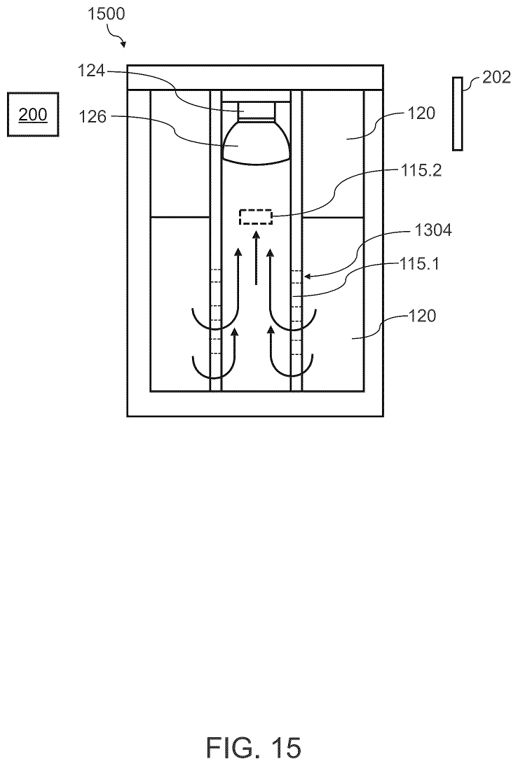

In FIG. 15, the crystal growth system 1500 includes the crystalline material 126 at the top of the crucible 118. Similar to FIG. 14, the interface structure 115.1 may include a tubular baffle structure. The crystalline material 126 may be within the interface structure 115.1. The interface structure 115.1 may be graphite, such as porous graphite. The interface structure 115.1 may include one or more apertures 1304 that assist in the transport of source vapor from the source material 120 to the crystalline material 126. The system 1500 may further include one or more second interface structures 115.2. The one or more second interface structures 115.2 may be arranged in the vapor transport path between the source material 120 and the crystalline material 126. Source vapor may be transported through the interface structures 115.1 and 115.2. The one or more second interface structure(s) 115.2 may be graphite, such as porous graphite. The interface structure 115.2 may include a baffle structure. The interface structure 115.2 may include one or more apertures.

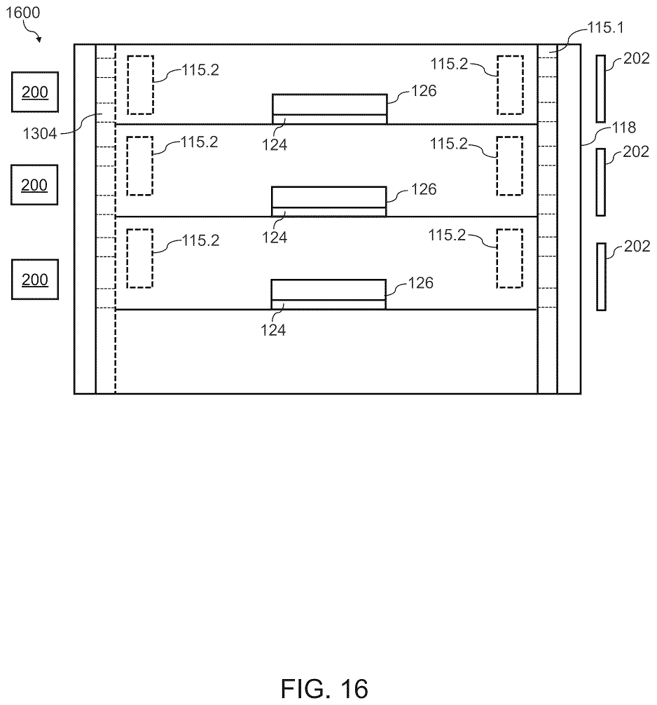

FIG. 16 depicts an example crystal growth system 1600 that may be used to grow a plurality of silicon carbide boules according to example embodiments of the present disclosure. In FIG. 16, the crystal growth system 1600 includes a plurality of seed holders 124 and crystalline material 126 arranged in different crystal growth chambers. The interface structure 115.1 may separate the crystalline material 126 from the source material 120. As depicted in FIG. 16, the interface structure 115.1 may include one or more apertures 1304 to assist with vapor transport from the source material 120 to the crystalline material 126. The crystal growth system 1600 may include one or more second interface structures 115.2 in each chamber. The interface structure(s) 115.2 may be arranged in the vapor transport path between the source material 120 and the crystalline material 126 in each chamber. Source vapor may be transported through the interface structure 115.1 and/or the interface structure 115.2. The one or more second interface structure(s) 115.2 may be graphite, such as porous graphite. The interface structure 115.2 may include a baffle structure. The interface structure 115.2 may include one or more apertures.

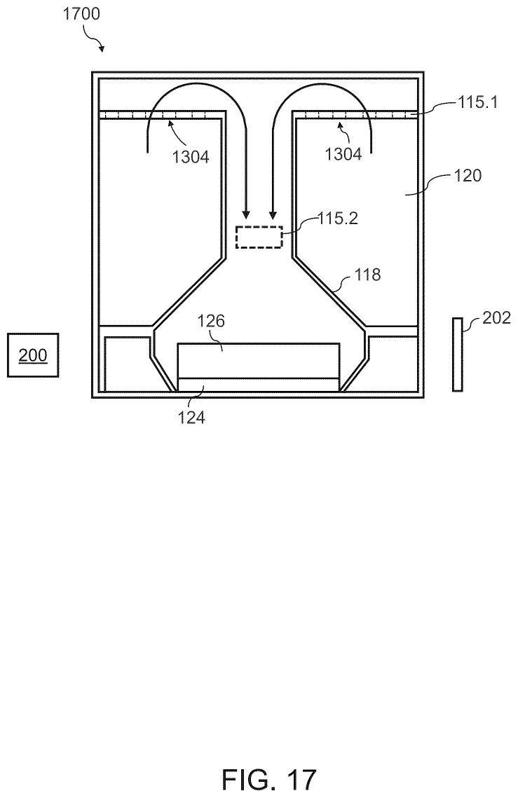

FIG. 17 depicts an example crystal growth systems 1700 according to example embodiments of the present disclosure. In FIG. 17, the crystal growth system 1700 includes the seed holder 124 and the crystalline material 126 arranged within a crucible 118. The crucible 118 may have one or more angled sidewalls. The crystal growth system 1700 includes a source material 120. The interface structure 115.1 may be on top of the source material 120 and may separate the source material 120 from the reaction chamber defined by the crucible 118. As depicted in FIG. 17, the interface structure 115.1 may include one or more apertures 1304 to assist with vapor transport from the source material 120 to the crystalline material 126. The crystal growth system 1700 may include one or more second interface structures 115.2. The interface structure(s) 115.2 may be arranged in the vapor transport path between the source material 120 and the crystalline material 126. Source vapor may be transported through the interface structure 115.1 and/or the interface structure 115.2. The one or more second interface structure(s) 115.2 may be graphite, such as porous graphite. The interface structure 115.2 may include a baffle structure. The interface structure 115.2 may include one or more apertures.

For any of the crystal growth systems provided herein, one or more parts of the crystal growth system or the source material may be 3D printed, such as disclosed in U.S. application Ser. No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

The technology discussed herein makes reference to servers, databases, software applications, and other computer-based systems, as well as actions taken and information sent to and from such systems. The inherent flexibility of computer-based systems allows for a great variety of possible configurations, combinations, and divisions of tasks and functionality between and among components. For instance, processes discussed herein can be implemented using a single device or component or multiple devices or components working in combination. Databases and applications can be implemented on a single system or distributed across multiple systems. Distributed components can operate sequentially or in parallel.

In an aspect, the present disclosure provides an example method. In some implementations, the example method includes obtaining, during a crystal growth process, measured data of a physical property of a crystalline material in a crystal growth system. In some implementations, the example method includes determining, based on the measured data, a crystal parameter associated with the crystalline material. In some implementations, the example method includes adjusting, based on the crystal parameter, one or more process parameters of the crystal growth process during the crystal growth process.

In some implementations of the example method, the measured data includes one or more images.

In some implementations of the example method, the measured data includes x-ray image data.

In some implementations of the example method, the measured data includes a two-dimensional representation of three-dimensional data associated with the crystalline material.

In some implementations of the example method, the measured data includes ultrasound data.

In some implementations of the example method, the measured data includes laser data.

In some implementations of the example method, the measured data includes optical data.

In some implementations of the example method, the measured data includes inductive current data.

In some implementations of the example method, the crystalline material includes silicon carbide.

In some implementations of the example method, the crystal growth system includes a plurality of imaging detectors.

In some implementations of the example method, the plurality of imaging detectors each comprise an imaging surface proximate to an outer surface of the crystal growth system.

In some implementations of the example method, the one or more process parameters comprise one or more of temperature, pressure, coolant flow rate, flux, growth segment time duration, heating element position, crucible position, crucible position relative to heating element position, insulation position, crystal position, source position, or rotation of the crystal.

In some implementations of the example method, the crystal growth process includes a plurality of growth segments, and the measured data is obtained during each of the plurality of growth segments.

In some implementations of the example method, the one or more process parameters are adjusted during each of the plurality of growth segments.

In some implementations of the example method, the crystal growth system includes an imaging device that obtains the measured data during the crystal growth process.

In some implementations of the example method, the imaging device is actuatable between a first imaging detector and a second imaging detector.

In some implementations of the example method, the crystalline material is between the first imaging detector, the second imaging detector and the imaging device.

In some implementations of the example method, the imaging device is an x-ray imaging device.

In some implementations of the example method, the crystal growth system includes a sensing coil that obtains the measured data during the crystal growth process.

In some implementations of the example method, the crystalline material is within the sensing coil.

In some implementations of the example method, the measured data is inductive current data.

In some implementations of the example method, the crystal parameter includes crystal growth height or crystal growth rate.

In some implementations of the example method, the crystal parameter includes one or more of shape, doping, crystal stress, one or more optical properties of the crystalline material, or uniformity.

In an aspect, the present disclosure provides an example crystal growth system. In some implementations, the example crystal growth system includes a seed holder configured to hold a seed crystal for growth of the silicon carbide crystalline material. In some implementations, the example crystal growth system includes a crucible at least partially defining a crystal growth chamber. In some implementations, the example crystal growth system includes a source material. In some implementations, the example crystal growth system includes one or more heating elements. In some implementations, the example crystal growth system includes a sensor for measuring a physical property of the crystalline material. In some implementations, the example crystal growth system includes a control system configured to adjust one or more process parameters during a crystal growth process based at least in part on the physical property of the crystalline material.

In some implementations of the example crystal growth system, the crystalline material includes silicon carbide.

In some implementations of the example crystal growth system, the sensor includes an imaging device.

In some implementations of the example crystal growth system, the imaging device includes an imaging sensor proximate to an outer surface of the crystal growth chamber.

In some implementations of the example crystal growth system, the imaging device captures one or more images after each of a plurality of growth segments.

In some implementations of the example crystal growth system, the imaging device is an x-ray imaging device.

In some implementations of the example crystal growth system, the imaging sensor is actuatable between a first plane and a second plane.

In some implementations, the example crystal growth system includes a first imaging detector. In some implementations, the example crystal growth system includes a second imaging detector.

In some implementations of the example crystal growth system, the imaging sensor is actuatable between the first imaging detector and the second imaging detector.

In some implementations of the example crystal growth system, the sensor includes a sensing coil around the crystal growth chamber.

In some implementations of the example crystal growth system, the sensor generates inductive current data.

In some implementations of the example crystal growth system, the sensor is configured to obtain one or more of ultrasound data, acoustic data, laser data, or optical data.

In an aspect, examples of the present disclosure are directed to a system for monitoring growth of a crystalline material. The system includes one or more sensors. The system includes processing circuitry configured to perform operations. The operations include: obtaining, during a crystal growth process, measured data indicative of a physical property of a crystalline material in a crystal growth system; determining, based on the measured data, a crystal parameter associated with the crystalline material; and adjusting, based on the crystal parameter, one or more process parameters of the crystal growth process.

In some implementations of the example system, the measured data includes one or more images.

In some implementations of the example system, the measured data includes x-ray image data.

In some implementations of the example system, the measured data includes a two-dimensional representation of three-dimensional data associated with the crystalline material.

In some implementations of the example system, the measured data includes ultrasound data.

In some implementations of the example system, the measured data includes laser data.

In some implementations of the example system, the measured data includes optical data.

In some implementations of the example system, the measured data includes inductive current data.

In some implementations of the example system, the crystalline material includes silicon carbide.

In some implementations of the example system, the crystal growth system includes a plurality of imaging detectors.

In some implementations of the example system, the plurality of imaging detectors each comprise an imaging surface proximate to an outer surface of the crystal growth system.

In some implementations of the example system, the one or more process parameters comprise one or more of temperature, pressure, coolant flow rate, flux, growth segment time duration, heating element position, crucible position, or crucible position relative to heating element position, insulation position, crystal position, source position, or rotation of the crystal.

In some implementations of the example system, the crystal growth process includes a plurality of growth segments, and the measured data is obtained during each of the plurality of growth segments.

In some implementations of the example system, the one or more process parameters are adjusted during each of the plurality of growth segments.

In some implementations of the example system, the crystal growth system includes an imaging device that obtains the measured data during the crystal growth process.

In some implementations of the example system, the imaging device is actuatable between a first imaging detector and a second imaging detector.

In some implementations of the example system, the crystalline material is between the first imaging detector, the second imaging detector and the imaging device.

In some implementations of the example system, the imaging device is an x-ray imaging device.

In some implementations of the example system, the crystal growth system includes a sensing coil that obtains the measured data during the crystal growth process.

In some implementations of the example system, the crystalline material is within the sensing coil.

In some implementations of the example system, the measured data is inductive current data.

In some implementations of the example system, the crystal parameter includes crystal growth height or crystal growth rate.

In some implementations of the example system, the crystal parameter includes one or more of shape, doping, crystal stress, one or more optical properties of the crystalline material, or uniformity.

In an aspect, the present disclosure provides an example method. In some implementations, the example method includes obtaining, during a crystal growth process, one or more x-ray images indicative of a physical property of a crystalline material in a crystal growth system. In some implementations, the example method includes determining, based on the one or more x-ray images, a crystal parameter associated with the crystalline material. In some implementations, the example method includes adjusting, based on the crystal parameter, one or more process parameters of the crystal growth process.

In some implementations of the example method, the one or more x-ray images are two-dimensional images.

In some implementations of the example method, the one or more x-ray images are three-dimensional images.

In some implementations of the example method, the crystalline material includes silicon carbide.

In some implementations of the example method, the crystal growth system includes a plurality of imaging detectors.

In some implementations of the example method, the plurality of imaging detectors each comprise an imaging surface proximate to an outer surface of the crystal growth system.

In some implementations of the example method, the one or more process parameters comprise one or more of temperature, pressure, coolant flow rate, flux, growth segment time duration, heating element position, crucible position, or crucible position relative to heating element position, insulation position, crystal position, source position, or rotation of the crystal.

In some implementations, the example method includes adjusting a position of the crystalline material within the crystal growth system based on the crystal parameter.

In some implementations of the example method, the crystal growth process includes a plurality of growth segments, and the one or more x-ray images are obtained during each of the plurality of growth segments.

In some implementations of the example method, the crystal growth system includes an imaging device that obtains the one or more x-ray images during the crystal growth process.

In some implementations of the example method, the imaging device is actuatable between a first imaging detector and a second imaging detector.

In some implementations of the example method, the crystal parameter includes crystal growth height or crystal growth rate.

In some implementations of the example method, the crystal parameter includes one or more of shape, doping, crystal stress, one or more optical properties of the crystalline material, or uniformity.

In an aspect, the present disclosure provides an example method. In some implementations, the example method includes obtaining, during a crystal growth process, inductive current data indicative of a physical property of a crystalline material in a crystal growth system. In some implementations, the example method includes determining, based on the inductive current data, a crystal parameter associated with the crystalline material. In some implementations, the example method includes adjusting, based on the crystal parameter, one or more process parameters of the crystal growth process.

In some implementations of the example method, the crystalline material includes silicon carbide.

In some implementations of the example method, the one or more process parameters comprise one or more of temperature, pressure, coolant flow rate, flux, growth segment time duration, heating element position, crucible position, or crucible position relative to heating element position, insulation position, crystal position, source position, or rotation of the crystal.

In some implementations, the example method includes adjusting a position of the crystalline material within the crystal growth system based on the crystal parameter.

In some implementations of the example method, the crystal growth process includes a plurality of growth segments, and the inductive current data is obtained during each of the plurality of growth segments.

In some implementations of the example method, the crystal growth system includes a sensing coil that obtains the inductive current data during the crystal growth process.

In some implementations of the example method, the crystalline material is within the sensing coil.

In some implementations of the example method, the crystal parameter includes crystal growth height or crystal growth rate.

In some implementations of the example method, the crystal parameter includes one or more of shape, doping, crystal stress, one or more optical properties of the crystalline material, or uniformity.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method, comprising:
obtaining, during a crystal growth process, measured data of a physical property of a crystalline material in a crystal growth system;
determining, based on the measured data, a crystal parameter associated with the crystalline material; and
adjusting, based on the crystal parameter, one or more process parameters of the crystal growth process during the crystal growth process.

2. The method of claim 1, wherein the measured data comprises one or more images.

3. The method of claim 1, wherein the measured data comprises x-ray image data.

4. The method of claim 3, wherein the measured data comprises a two-dimensional representation of three-dimensional data associated with the crystalline material.

5. The method of claim 1, wherein the measured data comprises ultrasound data.

6. The method of claim 1, wherein the measured data comprises laser data.

7. The method of claim 1, wherein the measured data comprises optical data.

8. The method of claim 1, wherein the crystalline material comprises silicon carbide.

9. The method of claim 1, wherein the crystal growth system comprises a plurality of imaging detectors.

10. The method of claim 9, wherein the plurality of imaging detectors each comprise an imaging surface proximate to an outer surface of the crystal growth system.

11. The method of claim 1, wherein the one or more process parameters comprise one or more of temperature, pressure, coolant flow rate, flux, growth segment time duration, heating element position, crucible position, crucible position relative to heating element position, insulation position, crystal position, source position, or rotation of the crystal.

12. The method of claim 1, wherein the crystal growth process comprises a plurality of growth segments and the measured data is obtained during each of the plurality of growth segments.

13. The method of claim 12, wherein the one or more process parameters are adjusted during each of the plurality of growth segments.

14. The method of claim 1, wherein the crystal growth system comprises an imaging device that obtains the measured data during the crystal growth process, wherein the imaging device is actuatable between a first imaging detector and a second imaging detector.

15. The method of claim 14, wherein the crystalline material is between the first imaging detector, the second imaging detector and the imaging device.

16. The method of claim 1, wherein the crystal growth system comprises a sensing coil that obtains the measured data during the crystal growth process, wherein the crystalline material is within the sensing coil, wherein the measured data is inductive current data.

17. The method of claim 1, wherein the crystal parameter comprises crystal growth height or crystal growth rate.

18. The method of claim 1, wherein the crystal parameter comprises one or more of shape, doping, crystal stress, one or more optical properties of the crystalline material, or uniformity.

19. A crystal growth system for growing crystalline material, comprising:
a seed holder configured to hold a seed crystal for growth of the silicon carbide crystalline material;
a crucible at least partially defining a crystal growth chamber;
a source material;
one or more heating elements; and
a sensor for measuring a physical property of the crystalline material;
a control system configured to adjust one or more process parameters during a crystal growth process based at least in part on the physical property of the crystalline material.

20. A system for monitoring growth of a silicon carbide crystalline material, the system comprising:
one or more process monitoring sensors;
processing circuitry configured to perform operations, the operations comprising:
obtaining, during a crystal growth process, measured data indicative of a physical property of a crystalline material in a crystal growth system;
determining, based on the measured data, a crystal parameter associated with the crystalline material; and
adjusting, based on the crystal parameter, one or more process parameters of the crystal growth process.
